(19) United States
(12) Patent Application Publication
(10) Pub. No.: US 2006/0290000 A1
(43) Pub. Date: Dec. 28, 2006

(54) Composite metal layer formed using metal nanocrystalline particles in an electroplating bath

(76) Inventors: Wojciech Worwag, Queen Creek, AZ (US); Sriram Muthukumar, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/169,596

(22) Filed: Jun. 28, 2005

(51) Int. Cl. H01L 23/52; H01L 21/44; C25D 15/00

(52) U.S. Cl. 257/768; 257/774; 438/674; 438/686; 205/109; 205/80; 427/430.1

(57) ABSTRACT

A method for forming a composite metal layer on a substrate comprises providing nanocrystalline particles of a first metal, adding the nanocrystalline particles to a plating bath that contains ions of a second metal to form a colloid-like suspension, immersing the substrate in the plating bath, and causing a co-deposition of the second metal and the nanocrystalline particles of the first metal on the substrate to form the composite metal layer. The co-deposition may be caused by inducing a negative bias on the substrate and applying an electric current to the plating bath to induce an electroplating process. In the electroplating process, the ions of the second metal are reduced by the substrate and become co-deposited on the substrate with the nanocrystalline particles of the first metal to form the composite metal layer.

### BACKGROUND

During the manufacture of semiconductor wafers, an electroplating process may be used to deposit metal layers. The metal layers may then be etched or polished to form devices and/or interconnects for a plurality of integrated circuits that are being formed on the semiconductor wafer. For example, trenches and vias may be etched into dielectric layers using conventional masking and photolithography techniques, and these trenches and vias may be filled with a metal though an electroplating process to form interconnects. Copper metal is generally used in trenches and vias to form interconnects within the integrated circuits.

During the electroplating process, it is difficult to maintain an even current distribution in the electroplating bath across the surface of the semiconductor wafer. This is particularly true within high aspect trenches and vias. In addition, copper metal tends to undergo a self-annealing process after it has been deposited into a via through an electroplating process. These factors cause an exaggerated grain growth to occur, resulting in vias that are filled with copper metal having a random crystal size distribution. The random crystal size distribution causes changes to occur in the properties of the plated feature. FIG. 1 illustrates a via 100 within a dielectric layer 102 filled with copper metal using a conventional plating process. The copper metal is shown after it has undergone a self-annealing process to form copper crystals 104 of varying size.

Some work has been done to control the grain size of the copper crystals through the addition of various organic additives to the electroplating bath. There have also been attempts to control copper crystal grain size or orientation by controlling the plating power or the plating rate. These efforts have been unsuccessful and the presence of copper crystals having a random crystal size distribution is still a problem that affects the properties of the plated vias.

### BRIEF DESCRIPTION OF THE DRAWINGS

FIG. 1 illustrates a via filled using a prior art plating process.

FIG. 2 illustrates a via filled using an electroplating process according to an implementation of the invention.

FIG. 3 is a method for producing metal nanocrystalline particles.

FIG. 4 is a method for plating metal into a via in accordance with an implementation of the invention.

### DETAILED DESCRIPTION

Described herein are systems and methods of plating a metal onto a substrate, such as a semiconductor wafer, and in particular, the plating of metal into high aspect trenches or vias found on the substrate. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As previously noted, known electroplating processes and the self-annealing tendencies of copper metal generate randomly sized metal crystals that negatively affect the electrical and physical properties of high aspect vias. Therefore, in accordance with an implementation of the invention, metal nanocrystalline particles may be added to a plating bath used for electroplating metal onto a substrate and/or into a high aspect trench or via. In an alternate implementation, metal nanocrystalline particles may be added to a plating bath for an electroless plating process that is used to deposit metal onto a substrate and/or into a high-aspect trench or via.

The presence of the metal nanocrystalline particles in the plating bath discourages and/or prevents the deposited metal from forming randomly sized crystals within the trench or via. This results in a more homogenous plating of metal and thereby improves both the electrical and physical properties of the trench or via. The metal nanocrystalline particles used in implementations of the invention are substantially defect-free and substantially homogenous (i.e., the particles have a narrow grain size distribution).

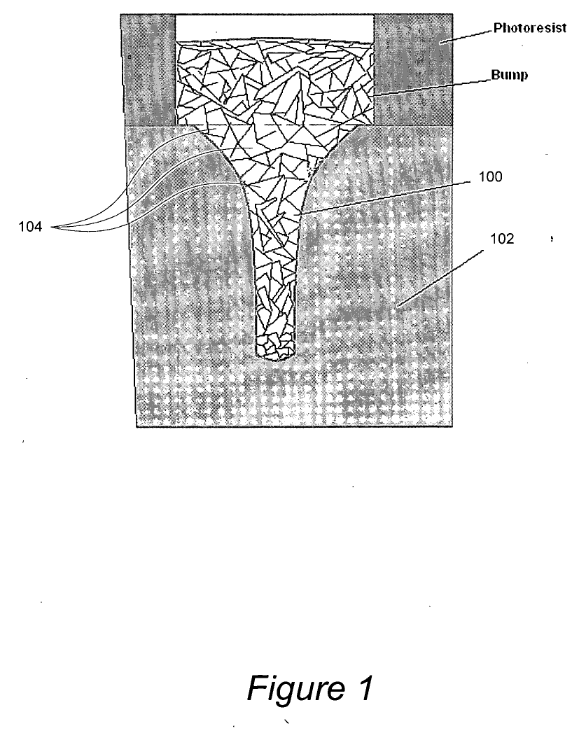

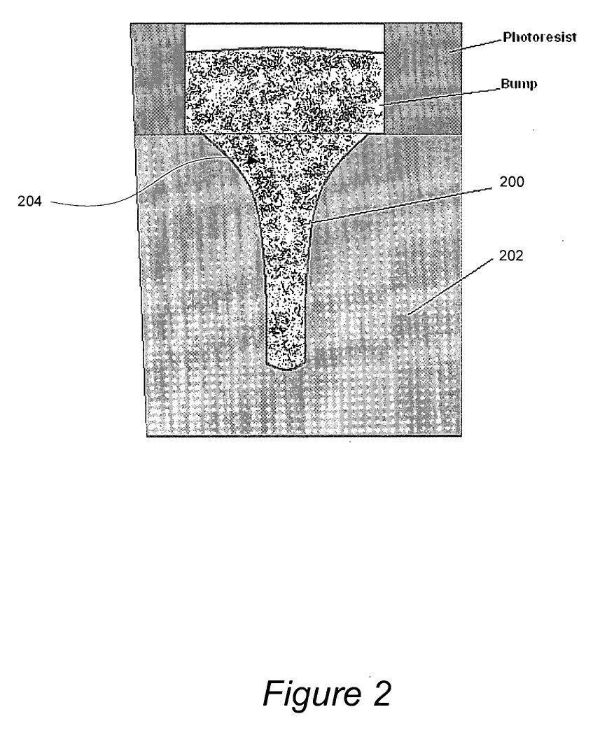

FIG. 2 illustrates a via 200 within a dielectric layer 202, where the via 200 is filled with a composite electroplated metal 204 using an electroplating process according to an implementation of the invention. The composite electroplated metal 204 consists of a plated metal formed from metal ions in a plating bath that is embedded with a plurality of metal nanocrystalline particles. As shown, the presence of metal nanocrystalline particles throughout the composite electroplated metal 204 causes the microstructure of the composite metal 204 to be very granular. This granularity is dependent on the amount and the distribution of nanocrystalline particles within the composite electroplated metal 204. The co-deposition of the nanocrystalline particles causes the grain size of the composite electroplated metal 204 in the via 200 to be preserved and prevents exaggerated grain growth from taking place because the copper crystal growth is limited by the nanocrystalline particles. As demonstrated in FIG. 2, this causes the metal deposition to be more homogenous relative to the conventional process shown in FIG. 1.

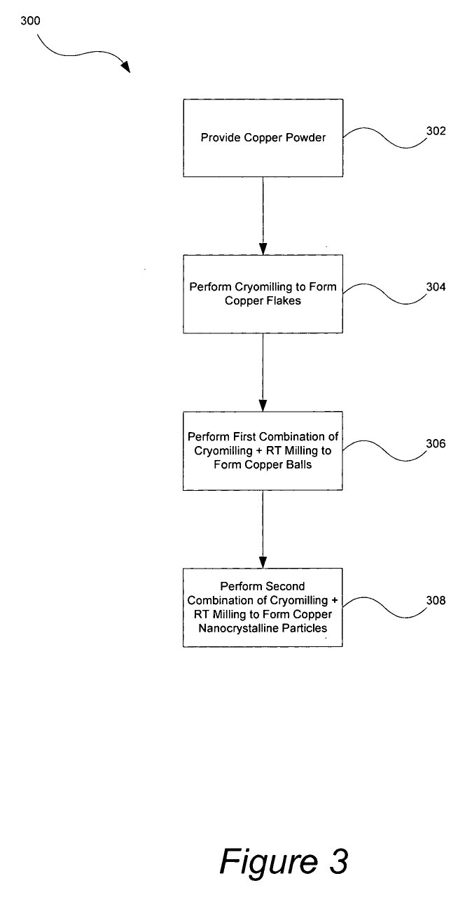

As is known in the art, metal nanocrystalline particles may be provided using many different sources or processes. For instance, FIG. 3 is a one known method 300 for producing metal nanocrystalline particles. Mechanical milling, also known as mechanical attrition or ball milling, has been widely used to synthesize nanostructured particles having a grain size of less than 100 nm. The mechanical milling process is generally performed at room temperature and in certain instances at liquid-nitrogen temperature, which is known as cryogenic mechanical milling or cryomilling. In both cases, the process is considered as cold deformation.

It has been shown that nanocrystalline copper particles may be produced using a combination of cryomilling and room temperature milling (RT milling). In one known method, copper powder is provided as the starting material (302). A cryomilling process is performed on the copper powder until the copper powder becomes flattened out and welded together to form thin rounded flakes (304). These copper flakes may be as large as 1 mm in diameter. The copper flakes are subjected to a first combination of cryomilling and RT milling processes to produce copper balls (306). This first milling combination and may induce an in situ consolidation of the copper flakes into the copper balls that range in size from 5 mm to 8 mm.

Next, the copper balls are subjected to a second combination of cryomilling and RT milling processes to produce copper nanocrystalline particles (308). For instance, a nanodrilling process using a focused ion beam directed at the copper balls may be used to generate the copper nanocrystalline particles. The resulting copper nanocrystalline particles generally have an average grain size of 25 nm with a relatively narrow grain size distribution. Generally, no grain size will exceed 50 nm. It has also been shown that the copper nanocrystalline particles produced by this method are substantially free of any crystal defects. In implementations on the invention, the metal nanocrystalline particles chosen for use in the plating bath may range from 0 nm to 100 nm, but will generally range from 0 nm to 50 nm. In some implementations, the metal nanocrystalline particles chosen for use in the plating bath may range from 20 nm to 50 nm.

Another process for generating metal nanocrystalline particles is semiconductor processing waste recovery. For example, a conventional chemical mechanical polishing process tends to generate metal nanocrystalline particles that are discarded in an outgoing waste stream. Processes exist whereby this waste stream may be processed or filtered to recover the metal nanocrystalline particles. These recovered metal nanocrystalline particles may be used in implementations of the invention. For instance, BOC Edwards of the United Kingdom markets a process that uses one or two ion exchange resin beds to remove copper from copper CMP polishing rinses. As is known in the art, this extracted copper may be processed using hydrothermal processes, chemical reduction processes, pyrolysis, and other processes to generate copper nanocrystalline particles.

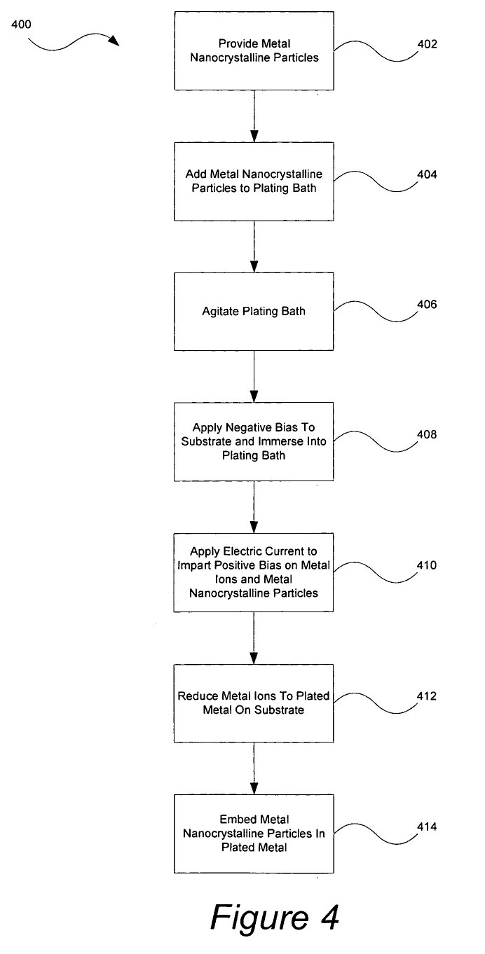

FIG. 4 is an electroplating process 400 carried out in accordance with an implementation of the invention. The electroplating process 400 may be carried out to plate a composite metal layer on a substrate, such as a semiconductor wafer. The substrate or semiconductor wafer may have one or more features that include, but are not limited to, high aspect trenches and high aspect vias. It should be noted that the substrate may be something other than a semiconductor wafer, and the methods of the invention described herein are not limited to semiconductor manufacturing processes. In an implementation, the composite metal layer consists of metal electroplated out of a plating bath that is embedded with a plurality of metal nanocrystalline particles.

The metal nanocrystalline particles are provided for the electroplating process (402). In some implementations, the nanocrystalline particles may be provided by generating the particles through a milling process, where the milling process includes any or all of cryomilling, RT milling, and nanodrilling. In some implementations, the nanocrystalline particles may be provided by recovering the particles from a semiconductor processing waste stream. In further implementations, the nanocrystalline particles may be acquired, for instance, by purchasing the nanocrystalline particles from a vendor. Other methods known in the art, but not disclosed herein, may also be used to acquire the metal nanocrystalline particles.

The provided metal nanocrystalline particles may be added to a plating bath for the electroplating process (404). When added, the metal nanocrystalline particles tend to become suspended in the plating bath in a colloidal-like suspension. Their relatively small size prevents the metal nanocrystalline particles from settling out of the plating bath. In addition, intra-molecular forces between the nanocrystalline particles and the plating bath components may further prevent the nanocrystalline particles from settling out of the liquid. Therefore, the metal nanocrystalline particles tend to remain suspended in the plating bath and form the colloid-like suspension, also known in the industry as a nanofluid. In some implementations, additives such as organics may be introduced in the plating bath to further prevent the metal nanocrystalline particles from settling out of the plating bath. In some implementations, organics such as polyethylene glycol may be used.

As mentioned above, the metal nanocrystalline particles used in the plating bath may range in size from 0 nm to 100 nm, but any range that has a relatively narrow grain size distribution and that maintains the nanocrystalline particles in a colloid-like suspension may be used. Metal nanocrystalline particles that are too large, for example greater than 100 nm, may not be used if they cannot remain suspended in the plating bath.

In implementations, the amount of metal nanocrystalline particles added to the plating bath should be sufficient to produce a concentration of 0% to 25% in the composite metal layer to be plated on the substrate. In some implementations, the concentration of metal nanocrystalline particles may be 1% to 10%, and in some implementations the concentration may be 2% to 3%. If the concentration of metal nanocrystalline particles is too high, for example greater than 25%, the metal nanocrystalline particles may be unable to maintain a colloid-like suspension in the plating bath. Furthermore, as the concentration of metal nanocrystalline particles in the final plated metal layer increases past 25%, the positive effects that the nanocrystalline particles have on yield strength and ductility may become compromised.

In some implementations of the invention, the metal used in the nanocrystalline particles may match the metal being deposited by the plating bath. For example, copper nanocrystalline particles may be added to a plating bath containing copper ions. In other implementations of the invention, the metal used in the nanocrystalline particles may be different than the metal deposited by the plating bath. For example, tin nanocrystalline particles may be added to a plating bath containing copper ions. Metals that may be used to form the nanocrystalline particles include, but are not limited to, copper (Cu), tin (Sn), aluminum (Al), gold (Au), platinum (Pt), palladium (Pd), rhodium (Rh), ruthenium (Ru), osmium (Os), silver (Ag), iridium (Ir), titanium (Ti), and alloys of any or all of these metals. Similarly, metal ions that may be used in the plating bath may include, but are not limited to, ions of Cu, Sn, Al, Au, Pt, Pd, Rh, Ru, Os, Ag, Ir, or Ti.

In various implementations of the invention, any of the above mentioned metal nanocrystalline particles may be used in any of the above mentioned electroplating baths. For example, gold or tin nanocrystalline particles may be used in an electroplating bath containing copper ions. The gold or tin nanocrystalline particles then become co-deposited with the copper metal. Similarly, copper, gold, or tin nanocrystalline particles may be used in electroplating baths containing gold ions or tin ions.

In implementations of the invention, the electroplating bath may further include an acid, water, and one or more additives such as surfactants, reducing agents, and organic constituents. For example, an acid copper electroplating solution may include water, sulfuric acid, copper sulfate, and hydrochloric acid. The acid copper electroplating solution may also include a number of organic constituents that serve to regulate and distribute the delivery of copper to the substrate being plated. Organic constituents typically include suppressors (e.g., polymers such as polyethylene glycols), accelerators (e.g., sulfur-containing compounds), and levelers (e.g., secondary suppressors).

The plating bath may be agitated to create a fluid flow across the substrate being plated and within high aspect trenches, vias, and other features found on the substrate (406). This fluid flow allows a greater proportion of metal ions and suspended metal nanocrystalline particles to come into contact with a greater portion of the surface of the substrate. The fluid flow also helps the plating bath penetrate into the high aspect trenches and vias. In some implementations, the plating bath may be maintained at a temperature that ranges from 15° C. to 50° C. and a pH level that ranges from pH 0 to pH 2.

The substrate being plated is given a negative bias and immersed in the plating bath (408). The substrate will function as a cathode in the electroplating process 400. An electric current is applied to the plating bath, thereby imparting a positive charge on the metal ions in solution and on the metal nanocrystalline particles (410). In some implementations, the electric current may have a current density, measured in amperes per square decimeter (ASD), of 0 ASD to 10 ASD. The positively biased metal ions and metal nanocrystalline particles are driven towards the negatively biased substrate. The “cathode” substrate provides the electrons to reduce the positively charged metal ions to metallic form, thereby causing the metal ions to become deposited on the substrate as a plated metal (412). The metal nanocrystalline particles are also deposited at the “cathode” substrate and become embedded within the plated metal (414).

The metal nanocrystalline particles tend to co-deposit proportionately to their concentration in the plating bath. In implementations of the invention, the concentration of metal nanocrystalline particles in the plating bath may be adjusted through agitation of the plating bath, varying the organics concentration, and varying the applied electrical current. Increasing the concentration of metal nanocrystalline particles in the plating bath directly increases the concentration of metal nanocrystalline particles embedded in the plated metal. The net result is an increase in overall plating thickness for a given time duration which may increase in proportion to the volume of the co-deposited metal nanocrystalline particles.

The final result is a plated metal, such as copper metal, co-deposited with the metal nanocrystalline particles. This is also referred to herein as a composite metal layer. As described above, the composite metal layer shows high yield strength along with good ductility. The presence of the metal nanocrystalline particles throughout the composite metal layer tends to discourage or even physically obstruct the exaggerated grain growth of the metal crystals from occurring, thereby reducing or eliminating the random crystal size distribution that generally occurs in metals such as copper that are deposited using conventional methods. The inclusion of the metal nanocrystalline particles may also provide better void control within the plated features. High aspect trenches and vias are therefore filled with a relatively more homogenous composite metal layer.

The magnitude of the effect that the metal nanocrystalline particles have on the composite metal layer is generally proportional to the concentration and size of the metal nanocrystalline particles in the composite metal layer. To an extent, as the amount and/or size of the nanocrystalline particles within the composite metal layer increases, the yield strength and ductility of the composite metal layer increases. The self-annealing properties of the metal are reduced as more nanocrystalline particles are added to the composite metal layer. This effect, however, is limited because at some point the concentration of metal nanocrystalline particles becomes too high and begins to have a detrimental effect on the composite metal layer. In some implementations, this concentration limit is approximately 25%. At that high a concentration, the nanocrystalline particles may begin to settle out of the plating bath, the physical properties of the composite metal layer may begin to be compromised, and metal nanocrystalline particles may begin to penetrate areas of the substrate where they may cause damage or short circuits. Therefore, in implementations of the invention, the concentration of embedded metal nanocrystalline particles in the composite metal layer is kept at or below 25%.

In an implementation of the invention, the applied electric current may be manipulated to vary the concentration of metal nanocrystalline particles in the final composite metal layer. It has been shown that increases in the applied current tend to have a greater effect on the metal ions in solution than on the metal nanocrystalline particles. So as the applied current is increased, the deposition rate of the metal ions increases faster than the deposition rate of the metal nanocrystalline particles. In other words, as the applied current is increased, the ratio of metal ions to nanocrystalline particles in the composite metal layer increases. The concentration of embedded nanocrystalline particles in the composite metal layer may therefore be decreased by increasing the applied current; similarly, the concentration of embedded nanocrystalline particles in the composite metal layer may be increased by decreasing the applied current. Accordingly, manipulation of the applied current may be used to create a gradient of embedded metal nanocrystalline particles in the composite metal layer. In some implementations, the current density may be manipulated between 1 ASD and 10 ASD to created the gradient.

In another implementation of the invention, metal alloys may be deposited on a substrate, including within high aspect trenches and vias. In conventional electroplating processes, alloys cannot be plated because an applied current will substantially move the metal ions of one, not both, metals in solution. In some situations, it is difficult to produce a plating bath with metal ions of two different metals. In implementations of the invention, however, alloys may be formed by creating a plating bath with ions of one of the metals to be alloyed, and the remaining metals to be alloyed may be provided as metal nanocrystalline particles. All of the metals to be alloyed become co-deposited during the electroplating process. The co-deposited metals may even be annealed in some implementations to further bond the metals together. Use of this implementation enables tin-gold alloys and tin-silver alloys to be formed.

In an implementation of the invention, the metal nanocrystalline particles may be added to a plating bath for an electroless plating process. Such a plating bath may further include a source metal (usually a salt), a reducer, a complexing agent to hold the metal in solution, and various buffers and other chemicals designed to maintain bath stability and increase bath life. Due to the chemical mechanism for an electroless plating process, the metal chosen for the metal nanocrystalline particles should match the metal ions in the plating bath. As such, copper nanocrystalline particles should be used in a copper plating bath, gold nanocrystalline particles should be used in a gold plating bath, and so on.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing nanocrystalline particles of a first metal;
adding the nanocrystalline particles to a plating bath to form a colloid-like suspension, wherein the plating bath comprises ions of a second metal;
immersing a substrate in the plating bath; and
causing codeposition of the second metal and the nanocrystalline particles of the first metal on the substrate to form a composite metal layer.

2. The method of claim 1, wherein the causing of the codeposition comprises:
imparting a negative bias on the substrate; and
applying an electric current to the plating bath to induce an electroplating process, wherein the ions of the second metal are reduced by the substrate and become co-deposited on the substrate with the nanocrystalline particles of the first metal to form the composite metal layer.

3. The method of claim 2, wherein the applied electric current has a current density between 0 and 10 ASD.

4. The method of claim 1, wherein the providing of the nanocrystalline particles comprises milling a metal to generate the nanocrystalline particles.

5. The method of claim 4, wherein the milling comprises one or more of cryomilling, room temperature milling, and nanodrilling.

6. The method of claim 1, wherein the adding of the nanocrystalline particles comprises adding a sufficient amount of the nanocrystalline particles to produce a nanocrystalline particle concentration of between 0% and 25% in the plating bath.

7. The method of claim 1, wherein the adding of the nanocrystalline particles comprises adding a sufficient amount of the nanocrystalline particles to produce a nanocrystalline particle concentration of between 1% and 5% in the plating bath.

8. The method of claim 1, further comprising increasing the ratio of the second metal to the first metal in the composite metal layer by increasing the applied electric current.

9. The method of claim 1, further comprising decreasing the ratio of the second metal to the first metal in the composite metal layer by decreasing the applied electric current.

10. The method of claim 1, wherein the substrate comprises a semiconductor wafer.

11. The method of claim 10, wherein the semiconductor wafer comprises a high aspect via.

12. The method of claim 1, wherein the first metal comprises Cu, Sn, Al, Au, Pt, Pd, Rh, Ru, Os, Ag, Ir, or Ti.

13. The method of claim 1, wherein the second metal comprises Cu, Sn, Al, Au, Pt, Pd, Rh, Ru, Os, Ag, Ir, or Ti.

14. The method of claim 1, wherein the second metal is the same as the first metal.

15. The method of claim 1, wherein the second metal is different than the first metal.

16. The method of claim 1, further comprising adding an organic additive to the plating bath to assist in forming the colloid-like suspension.

17. The method of claim 1, further comprising agitating the plating bath to create a fluid flow across the substrate.

18. The method of claim 1, further comprising maintaining the plating bath between 15° C. to 50° C.

19. The method of claim 1, further comprising maintaining the plating bath at a pH level that ranges from pH 0 to pH 2.

20. A plating bath comprising:
water;
a plurality of ions of a first metal;
an acid; and
a plurality of nanocrystalline particles of a second metal.

21. The plating bath of claim 20, wherein the plurality of ions of the first metal are provided by adding a salt of the first metal to the plating bath.

22. The plating bath of claim 20, wherein the first metal comprises Cu, Sn, Al, Au, Pt, Pd, Rh, Ru, Os, Ag, Ir, or Ti.

23. The plating bath of claim 20, wherein the second metal comprises Cu, Sn, Al, Au, Pt, Pd, Rh, Ru, Os, Ag, Ir, or Ti.

24. The plating bath of claim 20, wherein the first metal is the same as the second metal.

25. The plating bath of claim 20, wherein the first metal is different than the second metal.

26. The plating bath of claim 20, wherein the nanocrystalline particles are substantially free of any crystal defects and have a relatively narrow grain size distribution.

27. The plating bath of claim 26, wherein the nanocrystalline particles range in size from 0 nm to 70 nm.

28. The plating bath of claim 26, wherein the nanocrystalline particles range in size from 20 nm to 50 nm.

29. The plating bath of claim 20, further comprising:
a surfactant;
a reducing agent; and
an organic constituent.

30. The plating bath of claim 20, wherein the acid comprises sulfuric acid and hydrochloric acid, and wherein the plurality of ions of the first metal are provided by copper sulfate.

31. The plating bath of claim 30, further comprising at least one organic constituent.

32. The plating bath of claim 31, wherein the organic constituent comprises polyethylene glycol.

33. An apparatus comprising:
a via formed within a substrate; and
a composite metal layer filling the via.

34. The apparatus of claim 33, wherein the via comprises a high aspect via.

35. The apparatus of claim 34, wherein the composite metal layer comprises a plurality of nanocrystalline particles of a first metal embedded within a second metal.

36. The apparatus of claim 35, wherein the nanocrystalline particles of the first metal are substantially free of any crystal defects and have a relatively narrow grain size distribution.

37. The apparatus of claim 36, wherein the nanocrystalline particles of the first metal range in size from 0 nm to 70 nm.

38. The apparatus of claim 35, wherein the first metal comprises Cu, Sn, Al, Au, Pt, Pd, Rh, Ru, Os, Ag, Ir, or Ti.

39. The apparatus of claim 35, wherein the second metal comprises Cu, Sn, Al, Au, Pt, Pd, Rh, Ru, Os, Ag, Ir, or Ti.
